(19) United States
(12) Patent Application Publication
(10) Pub. No.: US 2025/0075319 A1
(43) Pub. Date: Mar. 6, 2025

(54) SUBSTRATE PROCESSING APPARATUS AND METHOD OF SUPPRESSING OXYGEN INCORPORATION

(71) Applicant: TOKYO ELECTRON LIMITED, Tokyo (JP)

(72) Inventors: Yuichi FURUYA, Yamanashi (JP); Ryuta MOCHIZUKI, Yamanashi (JP)

(21) Appl. No.: 18/951,419

(22) Filed: Nov. 18, 2024

Related U.S. Application Data
(63) Continuation of application No. PCT/JP2023/017728, filed on May 11, 2023.

(30) Foreign Application Priority Data
May 25, 2022 (JP) 2022-085097

(51) Int. Cl. C23C 16/448; C23C 16/06; C23C 16/44; C23C 16/455

(52) U.S. Cl. CPC C23C 16/448; C23C 16/06; C23C 16/4412; C23C 16/45587

(57) ABSTRACT

A substrate processing apparatus, includes: a chamber configured to be capable of being depressurized and accommodate a substrate; and an enclosure configured to enclose a supply source of a process gas supplied to the chamber and a connection pipe connecting the supply source and the chamber.

### CROSS-REFERENCE TO RELATED APPLICATION

This application is a bypass continuation application of International Patent Application No. PCT/JP2023/017728 having an international filing date of May 11, 2023 and designating the United States, the international application being based upon and claiming the benefit of priority from Japanese Patent Application No. 2022-085097, filed on May 25, 2022, the entire contents of which are incorporated herein by reference.

### TECHNICAL FIELD

The present disclosure relates to a substrate processing apparatus and a method of suppressing oxygen incorporation.

### BACKGROUND

Patent Document 1 discloses a processing system having a processing apparatus provided with a gas injector for injecting a predetermined raw material gas made of a metal compound material with a low vapor pressure into a processing container to perform a predetermined process on an object, and a gas supply system for supplying the predetermined raw material gas to the gas injector. In this processing system, the gas injector is a shower head. The gas supply system includes a gas passage extending upward from the shower head, a material storage tank installed at an upper end of the gas passage and accommodating the metal compound material therein, and an on-off valve for opening and closing the gas passage.

### PRIOR ART DOCUMENTS

### Patent Documents

Patent Document 1: Japanese Patent Laid-Open Publication No. 2009-239297

### SUMMARY

According to one embodiment of the present disclosure, there is provided a substrate processing apparatus, includes: a chamber configured to be capable of being depressurized and accommodate a substrate; and an enclosure configured to enclose a supply source of a process gas supplied to the chamber and a connection pipe connecting the supply source and the chamber.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory diagram schematically illustrating an outline of a configuration of a film forming apparatus as a substrate processing apparatus according to a first embodiment.

FIG. 2 is an explanatory diagram schematically illustrating an outline of a configuration of a film forming apparatus as a substrate processing apparatus according to a second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a manufacturing process of a semiconductor device and the like, various substrate processing processes, such as a film formation process, are sequentially performed on a substrate, such as a semiconductor wafer (hereinafter referred to as a “wafer”). These substrate processing processes are performed by a substrate processing apparatus. The substrate processing apparatus includes a chamber that is configured to be capable of being depressurized and accommodate the substrate during the substrate processing processes. In addition, depending on the substrate processing processes, various process gases are supplied to the chamber during processing. A process gas is supplied from a supply source of the process gas to the chamber through a connection pipe.

In order to seal a connection portion between the above-mentioned connection pipe and the chamber or a connection portion between the connection pipe and the supply source of the process gas, for example, an O-ring is used. If oxygen is unintentionally incorporated into the process gas supplied to the chamber, this may affect a processing result. Therefore, in order to further suppress the incorporation of oxygen through the above-mentioned connection portion into the process gas, a metal gasket may be used instead of the O-ring, or a double O-ring configuration in which double O-rings are disposed to supply an inert gas between an inner O-ring and an outer O-ring may be adopted.

However, there are cases in which application of neither the metal gasket nor the double O-rings is preferred. For example, when the supply source of the process gas is a vaporizer that stores a raw material having a low vapor pressure and vaporizes the raw material therein to generate a raw material gas as the process gas, it is not preferable to use the metal gasket or the double O-rings. Hereinafter, the reasons are described.

In the case of the vaporizer storing the raw material having the low vapor pressure, the above-mentioned connection pipe and the like are heated in order to prevent the raw material gas from resolidifying or reliquefying, so aluminum having a good thermal conductivity is sometimes used as a material for the connection pipe and the like. However, since aluminum has a low rigidity, it is difficult to apply the metal gasket to the connection pipe made of aluminum.

In addition, in the case of the vaporizer storing the raw material having the low vapor pressure, the vaporizer may be placed in the vicinity of the chamber and the chamber may be depressurized to depressurize an inside of the vaporizer and vaporize the raw material. In this case, the connection pipe is made large in diameter to reduce a pressure loss in the connection pipe. The application of the double O-rings to the connection pipe having the large diameter or to an on-off valve connected to the connection pipe is not common, and in the case of application, separate development is required, thereby resulting in high costs.

Therefore, a technique according to the present disclosure suppresses oxygen incorporation into the process gas supplied into the chamber of the substrate processing apparatus without adopting the metal gasket or the double O-rings.

Hereinafter, a substrate processing apparatus and a method of suppressing oxygen incorporation according to the present embodiment are described with reference to the drawings. In the present disclosure and the drawings, elements having substantially the same functional configuration are given the same reference numerals to avoid redundant explanation.

### First Embodiment

### <Film Forming Apparatus>

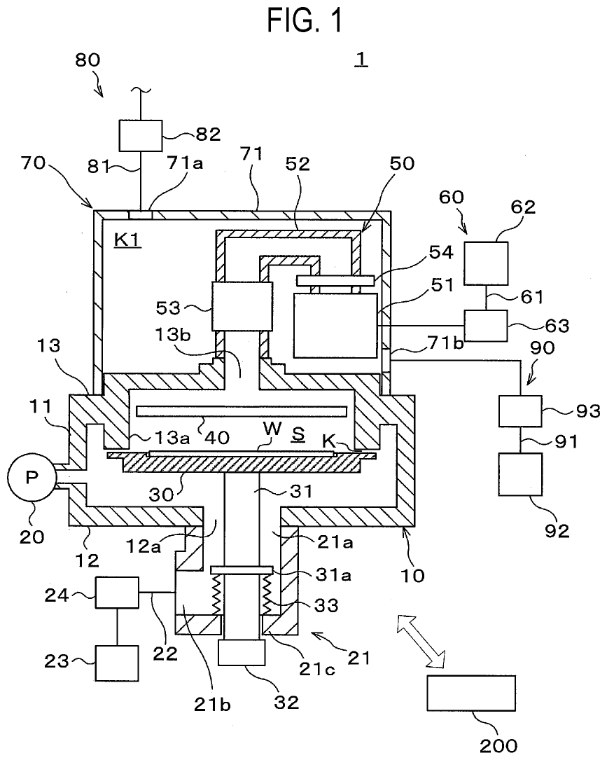

FIG. 1 is an explanatory diagram schematically illustrating an outline of a configuration of a film forming apparatus as a substrate processing apparatus according to a first embodiment, showing a cross-section of a part of the film forming apparatus.

A film forming apparatus 1 of FIG. 1 is configured to perform a film formation process as a substrate processing process on a wafer W serving as a substrate and form, for example, a ruthenium (RU) film on the wafer W.

The film forming apparatus 1 includes a chamber 10 which is configured to be capable of being depressurized and accommodates the wafer W.

The chamber 10 is formed so that, for example, an outer shape thereof is a rectangular parallelepiped and an internal space thereof has a cylindrical shape. A material of the chamber 10 is a metal material with a good thermal conductivity, for example, aluminum.

A side wall 11 of the chamber 10 is provided with a loading/unloading port (not shown) for the wafer W, and the loading/unloading port is provided with a gate valve (not shown) for opening and closing the loading/unloading port.

Further, a pressure sensor 20 provided outside the chamber 10 is connected to the side wall 11 of the chamber 10. The pressure sensor 20 is, for example, a capacitance manometer, and measures a pressure inside the chamber 10. A result measured by the pressure sensor 20 is output to a controller 200 to be described later.

An exhaust port 12a is formed at a bottom wall 12 of the chamber 10. In addition, an accommodator 21 that accommodates a bellows 33 to be described later is connected to the bottom wall 12 so that an opening 21a at an upper portion of the accommodator 21 communicates with the exhaust port 12a. The accommodator 21 includes openings 21a and 21b at the upper portion and a side portion, respectively, and the openings 21a and 21b communicate with each other. One end of an exhaust pipe 22 is connected to the opening 21b at the side portion of the accommodator 21 so that the chamber 10 is exhausted through these openings 21a and 21b. The other end of the exhaust pipe 22 is connected to an exhaust device (e.g., a vacuum pump) 23. In addition, an APC (Auto Pressure Controller) valve 24 is provided at an upstream of the exhaust device 23 of the exhaust pipe 22 as a pressure regulating valve for regulating the pressure inside the chamber 10. The APC valve 24 has an automatic pressure regulating function and a shutoff function, and an opening degree of the APC valve 24 is controlled based on a control signal from the controller 200 to be described later. The APC valve 24 may regulate the pressure inside the chamber 10 to a preset pressure or block a connection between the chamber 10 and the exhaust device 23.

In the chamber 10, a stage 30 on which the wafer W is horizontally placed is provided and the stage 30 has a circular shape in a plane view. A heater (not shown) for heating the wafer W is provided inside the stage 30. An upper end of a support member 31 extending in a vertical direction is connected to a center at a side of a lower surface of the stage 30 so that the support member 31 penetrates the bottom wall 12 through the exhaust port 12a of the bottom wall 12 of the chamber 10 and further penetrates a bottom wall 21c of the accommodator 21. A lower end of the support member 31 is connected to a lift 32. It is possible to move the stage 30 up and down between a first position of an upper portion thereof and a second position of a lower portion thereof by driving of the lift 32 controlled by the controller 200 to be described later.

The first position is a processing position at which the wafer W is processed. A processing space S is formed by the stage 30 located at the processing position and a partition wall 13a extending downward from a ceiling wall 13 of the chamber 10 to partition an inside and an outside of an inner space of the chamber 10. A gap K is formed between an upper surface of the stage 30 located at the processing position and a lower surface of the partition wall 13a, and the processing space S may be exhausted through this gap K.

The second position is a standby position at which the stage 30 waits while the wafer W is delivered between a transfer mechanism (not shown) for the wafer W that enters the chamber 10 from the aforementioned loading/unloading port (not shown) of the chamber 10 and a delivery pin (not shown) provided at a lower portion within the chamber 10.

Further, the support member 31 is provided with a flange 31a. The bellows 33 is provided to surround an outer periphery of the support member 31 between a lower surface of the flange 31a and an upper surface of the bottom wall 21c of the accommodator 21. Since this bellows 33 is provided, loss of airtightness of the chamber 10 caused by a penetration portion of the support member 31 at the bottom wall 21c of the accommodator 21 is prevented.

A shower head 40 is provided above the stage 30 in the chamber 10 in parallel with the stage 30 as a gas flow forming member for forming a flow of a raw material gas in the processing space S. By this shower head 40, the raw material gas supplied through a gas supply port 13b provided at a center of the ceiling wall 13 of the chamber 10 is rectified by passing through a plurality of holes provided at the shower head 40 and is supplied to the wafer W.

Further, a raw material gas supplier 50 that supplies the raw material gas to the chamber 10 is connected to the ceiling wall 13 of the chamber 10.

The raw material gas supplier 50 includes a vaporizer 51 as a supply source of a process gas.

The vaporizer 51 stores a raw material of the process gas, and the raw material is vaporized therein.

The raw material stored in the vaporizer 51 is a material that has a low vapor pressure and is solid or liquid at room temperature and pressure and, specifically, is, for example, a solid raw material Ru₃(CO)₁₂. Ru₃(CO)₁₂ becomes a raw material gas for forming a Ru film through vaporization, i.e., sublimation.

The vaporizer 51 is disposed to overlap the chamber 10 when viewed from above. Specifically, the vaporizer 51 is disposed so that the entirety thereof is fit into an inner side of the chamber 10 and there is no part that is lying outside the chamber 10 when viewed from above. More specifically, the vaporizer 51 is disposed so that the entirety thereof is fit into an inner side of an outer peripheral edge of the ceiling wall 13 of the chamber 10 and there is no part that is lying outside the ceiling wall 13 of the chamber 10 when viewed from above.

The vaporizer 51 may be placed directly on the ceiling wall 13 of the chamber 10 or may be placed on the ceiling wall 13 of the chamber 10 via a support member.

One end of a supply pipe 61 of a carrier gas supplier 60 that supplies a carrier gas such as carbon monoxide (CO) gas is connected to the vaporizer 51. The other end of the supply pipe 61 is connected to a supply source 62 of the carrier gas. The supply pipe 61 is provided with a flow-rate controller 63 including a flow-rate control valve (not shown) such as a mass flow controller or including an on-off valve that starts or stops supply of the carrier gas. Also, the supply pipe 61 is provided with a carrier gas heater (not shown) for heating the carrier gas. The flow-rate controller 63 or the carrier gas heater is controlled by the controller 200 to be described later. Further, the supply pipe 61 is provided with a temperature sensor (not shown) for controlling a temperature of the supply pipe 61. A result measured by the temperature sensor is output to the controller 200 to be described later.

The carrier gas supplied from the carrier gas supplier 60 to the vaporizer 51 is supplied to the chamber 10 via a connection pipe 52 to be described later together with the raw material gas generated by sublimation of the solid raw material.

The vaporizer 51 is provided with a vaporizer heater (not shown) so as to cover the entirety of the vaporizer 51. The vaporizer heater heats the vaporizer 51. Vaporization, i.e., sublimation, of the solid raw material in the vaporizer 51 may be promoted by heating the vaporizer heater. This vaporizer heater is controlled by the controller 200 to be described later.

Furthermore, the vaporizer 51 is provided with a pressure sensor (not shown) for measuring a pressure inside the vaporizer 51. The vaporizer 51 is also provided with a temperature sensor (not shown) for measuring a temperature of the vaporizer 51. A result measured by this pressure sensor or temperature sensor is output to the controller 200 to be described later.

The raw material gas supplier 50 also includes a connection pipe 52 that connects the vaporizer 51 to the chamber 10 in order to supply the raw material gas from the vaporizer 51. The connection pipe 52 is heated as described later, so aluminum, which has a good thermal conductivity, is used as a material of the connection pipe 52. One end of the connection pipe 52 is connected to the vaporizer 51, and the other end of the connection pipe 52 is connected to the ceiling wall 13 of the chamber 10. The inside of the vaporizer 51 and an inside of the chamber 10 communicate with each other via the connection pipe 52. Further, an O-ring is used instead of a metal gasket at a connection portion between the one end of the connection pipe 52 and the vaporizer 51 and at a connection portion between the other end of the connection pipe 52 and the ceiling wall 13 of the chamber 10, so that airtightness is not impaired at these connection portions. If the connection pipe 52 is made of a plurality of members, the O-ring is also used at a connection portion between these members instead of the metal gasket. Furthermore, in the film forming apparatus 1, double O-rings are not used at the connection portion between the one end of the connection pipe 52 and the vaporizer 51, the connection portion between the other end of the connection pipe 52 and the ceiling wall 13 of the chamber 10, and the connection portion between the above members.

The connection pipe 52 is provided with an on-off valve 53 that opens or closes a pipe passage in the connection pipe 52. The on-off valve 53 is controlled by the controller 200 to be described later.

An APC valve 54 is provided between the on-off valve 53 and the vaporizer 51 in the connection pipe 52 as a pressure regulating valve for regulating the pressure in the vaporizer 51. The APC valve 54 has an automatic pressure regulating function and a shutoff function, and an opening degree of the APC valve 54 is controlled based on a control signal from the controller 200 to be described later. The APC valve 54 may regulate the pressure in the vaporizer 51 to a preset pressure and close the pipe passage in the connection pipe 52.

The connection pipe 52 is provided with a connection pipe heater (not shown). The connection pipe heater heats the entirety of the connection pipe 52 including the on-off valve 53 and the APC valve 54. This makes it possible to prevent the raw material gas from re-solidifying and adhering to the connection pipe 52 including the on-off valve 53 and the APC valve 54.

In order to prevent the raw material gas from re-solidifying and adhering to an inner wall of the chamber 10, a chamber heater (not shown) for heating the chamber 10 is provided at the film forming apparatus 1.

The connection pipe heater and the chamber heater are controlled by the controller 200 to be described later.

In addition, the connection pipe 52 is provided with a temperature sensor (not shown) to control a temperature of the connection pipe 52 by using the connection pipe heater, and the chamber 10 is provided with a temperature sensor (not shown) to control a temperature of the chamber 10 by using the chamber heater. Results measured by these temperature sensors are output to the controller 200 to be described later.

Furthermore, the film forming apparatus 1 includes an enclosure 70.

The enclosure 70 encloses the vaporizer 51 and the connection pipe 52. Specifically, the enclosure 70 encloses the entirety of the vaporizer 51 and the entirety of the connection pipe 52 and also encloses a connection portion between the vaporizer 51 and the connection pipe 52 or a connection portion between the chamber 10 and the connection pipe 52.

The enclosure 70 is composed of the ceiling wall 13 of the chamber 10 and a cover 71. The cover 71 forms an accommodation space K1 for accommodating the vaporizer 51 and the connection pipe 52 between the cover 71 and the ceiling wall 13 of the chamber 10. The cover 71 is made of a metal material such as aluminum. The cover 71 is formed, for example, in a rectangular cylindrical shape with an open lower portion, and an opening of the lower portion is closed by the ceiling wall 13 of a rectangular shape in a plane view. The cover 71 is fixed to, for example, the ceiling wall 13. The cover 71 and the ceiling wall 13 are fixed using, for example, screws.

The cover 71 is formed and disposed so that the entirety of the cover 71 is fit into the inner side of the chamber 10 and there is no part that is lying outside the chamber 10 when viewed from above. Specifically, the cover 71 is formed and disposed so that the entirety of the cover 71 is fit into the inner side of the outer peripheral edge of the ceiling wall 13 of the chamber 10 and there is no part that is lying outside the ceiling wall 13 of the chamber 10 when viewed from above.

A supply port 71a and an exhaust port 71b are formed at the cover 71.

One end of a supply pipe 81 of an inert gas supplier 80 that supplies an inert gas such as nitrogen (N₂) gas into the enclosure 70, i.e., the accommodation space K1, is connected to the supply port 71a. The other end of the supply pipe 81 is connected to a supply source of the inert gas (not shown). The supply pipe 81 is provided with a flow-rate controller 82 including a flow-rate control valve (not shown) such as a mass flow controller or including an on-off valve that starts or stops supply of the inert gas. The flow-rate controller 82 is controlled by the controller 200 to be described later.

One end of an exhaust pipe 91 of an exhauster 90 that exhausts the enclosure 70, i.e., the accommodation space K1, is connected to the exhaust port 71b. The other end of the exhaust pipe 91 is connected to an exhaust device (e.g., a vacuum pump) 92. In addition, an exhaust amount regulator 93 that regulates an amount of exhaust is connected to the exhaust pipe 91. The exhaust amount regulator 93 includes a flow-rate control valve or an on-off valve that starts and stops exhaust. The exhaust amount regulator 93 is controlled by the controller 200 to be described later.

The film forming apparatus 1 configured as described above is provided with the controller 200. The controller 200 is configured by a computer equipped with a processor, such as a CPU, or a memory and includes a program storage (not shown). The program storage stores a program for realizing processing of the wafer W by the film forming apparatus 1. The program has been recorded in a computer-readable storage medium and may be installed in the controller 200 from the storage medium. The storage medium may be transitory or non-transitory.

### <Wafer Processing>

Next, an example of wafer processing by the film forming apparatus 1 is described. The wafer processing is automatically performed under control of the controller 200.

First, in a state in which the on-off valve 53, the on-off valve of the flow-rate controller 63, and the APC valve 54 are in a closed state, the opening degree of the APC valve 24 is regulated based on the result measured by the pressure sensor 20, and the pressure inside the chamber 10 is set to a predetermined pressure. In this state, a gate valve (not shown) provided at the loading/unloading port (not shown) for the wafer W of the chamber 10 is opened, and the transfer mechanism (not shown) holding the wafer W is inserted into the chamber 10 through the loading/unloading port from a transfer chamber (not shown), which is adjacent to the chamber 10 and has a vacuum atmosphere. The wafer W is then transferred to a position above the stage 30 located at the standby position described above. The wafer W is transferred onto raised support pins (not shown), the transfer mechanism is removed from the chamber 10, and then the gate valve is closed. At the same time, the support pins are lowered, the stage 30 is raised, the wafer W is placed on the stage 30, and the stage 30 is moved to the processing position described above, thereby forming the processing space S.

Next, the wafer W is heated to a predetermined temperature (e.g., 120 to 250 degrees C.) by the heater provided in the stage 30.

When a temperature of the wafer W reaches the predetermined temperature, the opening degree of the APC valve 24 is regulated, and the pressure inside the chamber 10 is reduced to a predetermined pressure (e.g., 5 mTorr to 100 mTorr).

When the pressure inside the chamber 10 is reduced, the on-off valve 53 and the on-off valve of the flow-rate controller 63 are opened, and the opening degree of the APC valve 54 is regulated so that the supply of the raw material gas to the processing space S inside the chamber 10 is started. This starts the formation of the Ru film on the wafer W in the processing space S by chemical vapor deposition (CVD). The opening degree of the APC valve 54 is regulated to increase gradually, for example, from after the on-off valve 53 and the like are opened, until the pressure inside the vaporizer 51 reaches a set pressure (e.g., 40 mTorr to 150 mTorr). When the pressure inside the vaporizer 51 reaches the set pressure, the opening degree of the APC valve 54 is regulated so that the pressure inside the vaporizer 51 remains constant at the set pressure until the formation of the Ru film is completed.

When the formation of the Ru film is completed, the on-off valve 53 and the on-off valve of the flow-rate controller 63 are closed, and the wafer W is unloaded from the chamber 10 in a reverse order to the above order.

During the Ru film formation process, i.e., for a time during which the on-off valve 53 and the on-off valve of the flow-rate controller 63 are opened and then closed, a carrier gas heated to a predetermined temperature (e.g., 80 degrees C.) is supplied at a constant flow rate by the carrier gas heater (not shown).

During the above-described wafer processing process, the temperatures of the vaporizer 51, the connection pipe 52, and the chamber 10 are constantly heated by the above-mentioned vaporizer heater, connection pipe heater, and chamber heater so as to be constant at predetermined temperatures based on results measured by the corresponding temperature sensors, so that at least the raw material gas does not resolidify. For example, the connection pipe 52 and the chamber 10 are heated and controlled to be constant at 80 degrees C., and the vaporizer 51 is heated and controlled so as to be constant at a predetermined temperature which is from a temperature slightly lower than the temperature of the connection pipe 52 or the chamber 10 to a temperature higher than the temperature of the connection pipe 52 or the chamber 10 and is lower than a decomposition temperature of the solid raw material (e.g., 70 degrees C. to 100 degrees C., which is lower than a decomposition temperature at the above set pressure).

Furthermore, during the wafer processing process, the flow-rate controller 82 of the inert gas supplier 80 or the exhaust amount regulator 93 of the exhauster 90 is controlled to supply an inert gas into the enclosure 70, i.e., the accommodation space K1. For example, during the wafer processing process, the accommodation space K1 is regulated to a positive pressure relative to an atmosphere outside the enclosure 70 so that air does not enter the accommodation space K1 from the outside of the enclosure 70.

### <Main Effect of Present Embodiment>

As described above, in this embodiment, the film forming apparatus 1 includes the enclosure 70 that encloses the vaporizer 51 of the process gas and the connection pipe 52. Therefore, by supplying the inert gas into the enclosure 70, i.e., the accommodation space K1, it is possible to suppress oxygen incorporation into the process gas supplied to the chamber 10 from connection portions with other members, for members enclosed by the enclosure 70, i.e., for members accommodated in the accommodation space K1. For example, it is possible to suppress oxygen incorporation into the process gas from the connection portion between the connection pipe 52 and the vaporizer 51 or the connection portion between the connection pipe 52 and the ceiling wall 13 of the chamber 10. In this embodiment, it is not necessary to adopt a metal gasket or double O-rings in order to suppress oxygen incorporation, as described above.

Furthermore, since it is possible to suppress oxygen incorporation into the process gas as described above, a film formed by the film forming apparatus 1 is capable of being suppressed from being affected by oxygen in the process gas.

In addition, despite having a simple shape, the enclosure 70 is enabled to enclose the vaporizer 51 and the connection pipe 52. Thereby, cost required for developing the enclosure 70 is not high. Therefore, it is possible to prevent high cost incurred due to suppression of oxygen incorporation.

Furthermore, in this embodiment, the enclosure 70 is composed of the ceiling wall 13 of the chamber 10 and the cover 71 that forms the accommodation space K1 between the cover 71 and the ceiling wall 13. When viewed from above, the cover 71 is fit into the inner side of the chamber 10 and there is no part of the cover 71 that is lying outside the chamber 10. Therefore, according to this embodiment, even if the enclosure 70 is provided, an occupation area, i.e., a footprint, of the film forming apparatus 1 is not increased.

### Second Embodiment

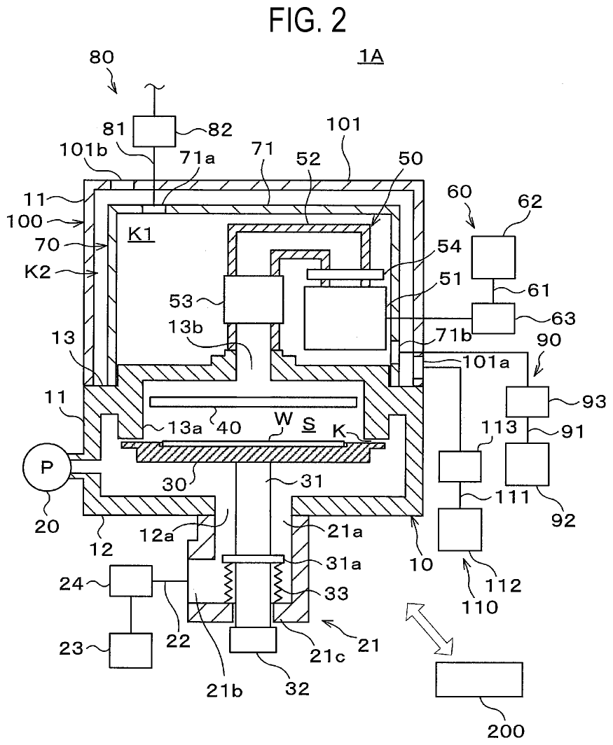

FIG. 2 is an explanatory diagram schematically illustrating an outline of a configuration of a film forming apparatus as a substrate processing apparatus according to a second embodiment, showing a cross-section of a part of the film forming apparatus.

The film forming apparatus 1A of FIG. 2 includes an enclosure 100 in addition to the configuration of the film forming apparatus 1 of FIG. 1.

The enclosure 100 encloses the enclosure 70. Specifically, the enclosure 100 encloses the entirety of the enclosure 70 and also encloses a connection portion between the enclosure 70 and the ceiling wall 13 of the chamber 10.

The enclosure 100 is composed of the ceiling wall 13 of the chamber 10 and a cover 101. The cover 101 forms an accommodation space K2 for accommodating the vaporizer 51 and the connection pipe 52 together with the cover 71 of the enclosure 70 between the cover 101 and the ceiling wall 13 of the chamber 10. The cover 101 is made of a metal material such as aluminum. The cover 101 is formed, for example, in a rectangular cylindrical shape with an open lower portion, and an opening of the lower portion is closed by the ceiling wall 13 of a rectangular shape in a plane view. The cover 101 is fixed to, for example, the ceiling wall 13. The cover 101 and the ceiling wall 13 are fixed using, for example, screws.

The cover 101 is formed and disposed so that the entirety of the cover 101 is fit into the inner side of the chamber 10 and there is no part that is lying outside the chamber 10 when viewed from above. Specifically, the cover 101 is formed and disposed so that the entirety of the cover 101 is fit into the inner side of the outer peripheral edge of the ceiling wall 13 of the chamber 10 and there is no part that is lying outside the ceiling wall 13 of the chamber 10 when viewed from above.

An exhaust port 101a and an introduction port 101b are formed at the cover 101.

One end of an exhaust pipe 111 of an exhauster 110 that exhausts the enclosure 100, i.e., the accommodation space K2, is connected to the exhaust port 101a. The other end of the exhaust pipe 111 is connected to an exhaust device (e.g., a vacuum pump) 112. An exhaust amount regulator 113 that regulates an amount of exhaust is connected to the exhaust pipe 111. The exhaust amount regulator 113 includes a flow-rate control valve or an on-off valve that starts and stops exhaust. The exhaust amount regulator 113 is controlled by the controller 200.

The introduction port 101b is opened toward an outside of the enclosure 100. Therefore, by exhausting an inside of the enclosure 100, i.e., the accommodation space K2, through the exhaust port 101a, gases other than an inert gas is introduced into the enclosure and, specifically, an atmosphere is introduced.

Even during a wafer processing process by the film forming apparatus 1A, the inert gas is supplied to an inside of the enclosure 70, i.e., the accommodation space K1, and the inside of the enclosure 70, i.e., the accommodation space K1, is exhausted in the same way as during the wafer processing process by the film forming apparatus 1 of FIG. 1.

During the wafer processing process by the film forming apparatus 1A, the exhaust amount regulator 113 of the exhauster 110 and the like are controlled to exhaust the inside of the enclosure 100, i.e., the accommodation space K2, and the atmosphere is introduced into the inside of the enclosure 100, i.e., the accommodation space K2. For example, during the wafer processing process, the accommodation space K2 is regulated to a negative pressure relative to the accommodation space KI and the atmosphere outside the enclosure 100 so that the atmosphere does not intrude into the accommodation space K1 from the accommodation space K2, and the atmosphere that may contain a raw material gas and a carrier gas in the accommodation space K2 does not leak to the outside of the enclosure 100.

According to the embodiment, even if the raw material gas and the carrier gas leak to the outside of the enclosure 70, it is possible to suppress the raw material gas and the carrier gas from leaking to an outside of the film forming apparatus 1A.

Furthermore, in the embodiment, the enclosure 100 is composed of the ceiling wall 13 of the chamber 10 and the cover 101 that forms the accommodation space K2 between the cover 101 and the ceiling wall 13. The cover 101 is fit into the inner side of the chamber 10 and there is no part that is lying outside the chamber 10 when viewed from above. Therefore, according to this embodiment, even if the enclosure 100 is provided, an occupied area, i.e., a footprint, of the film forming apparatus 1 does not increase.

### Modification

In the above description, while a technique according to the present disclosure has been applied to the film forming apparatus, the technique may also be applied to other substrate processing apparatuses such as an etching apparatus or a cleaning apparatus.

In the above description, exhaust from the inside of the enclosure 70 has been performed by using the exhauster 90. Instead of using the exhauster 90, the enclosure 70 may be pressurized by supplying an inert gas to the enclosure 70, and thereby allowing for performing the exhaust from the inside of the enclosure 70. In this case, members other than the exhaust pipe 91 of the exhauster 90 may be omitted.

It is to be noted that the embodiments disclosed herein are exemplary in all respects and are not restrictive. The above-described embodiments may be omitted, replaced, and/or modified in various forms without departing from the scope and spirit of the appended claims. For example, constituent elements of the above embodiments may be arbitrarily combined. From this arbitrary combination, it is needless to say that the operations and effects of the respective constituent elements related to the combination may be obtained, and other operations and other effects obvious to those skilled in the art may be obtained from the description of the present disclosure.

The effects described herein are illustrative or exemplary only and are not restrictive. That is, the technique of the present disclosure may obtain other effects obvious to those skilled in the art from the description herein in addition to or in place of the above effects.

The following configurations are also within a technical scope of the present disclosure.

### Supplementary Note 1

According to one aspect of the present disclosure, there is provided a substrate processing apparatus, including:

a chamber configured to be capable of being depressurized and accommodate a substrate; and an enclosure configured to enclose a supply source of a process gas supplied to the chamber and a connection pipe connecting the supply source and the chamber.

### Supplementary Note 2

In the substrate processing apparatus of Supplementary Note 1, a supply pipe configured to supply an inert gas into the enclosure and an exhaust pipe configured to exhaust the enclosure are connected to the enclosure.

### Supplementary Note 3

In the substrate processing apparatus of Supplementary Note 1 or 2, the supply source is a vaporizer configured to store a raw material of the process gas and internally vaporize the raw material.

### Supplementary Note 4

In the substrate processing apparatus of Supplementary Note 3, the raw material is solid or liquid at room temperature and pressure.

### Supplementary Note 5

In the substrate processing apparatus of Supplementary Note 4, the raw material is a raw material gas which forms a ruthenium film through vaporization.

### Supplementary Note 6

In the substrate processing apparatus of any one of Supplementary Notes 1 to 5, the supply source is disposed to overlap the chamber when viewed from above.

### Supplementary Note 7

In the substrate processing apparatus according to Supplementary Note 6, the enclosure is configured by:
a ceiling wall of the chamber; and
a cover configured to form an accommodation space, which accommodates the supply source and the connection pipe, between the cover and the ceiling wall, and
wherein the cover is formed to fit into an inner side of the chamber when viewed from above.

### Supplementary Note 8

In the substrate processing apparatus of any one of Supplementary Notes 1 to 5, the substrate processing apparatus further includes another enclosure configured to enclose the enclosure.

### Supplementary Note 9

The substrate processing apparatus of Supplementary Note 6, the substrate processing apparatus further includes another enclosure configured to enclose the enclosure.

### Supplementary Note 10

The substrate processing apparatus of Supplementary Note 7, the substrate processing apparatus further includes another enclosure configured to enclose the enclosure.

### Supplementary Note 11

In the substrate processing apparatus of Supplementary Note 10, the another enclosure includes:
the ceiling wall of the chamber; and
another cover configured to form another accommodation space, which accommodates the supply source and the connection pipe together with the cover, between the another cover and the ceiling wall,
wherein the another cover is formed to fit into the inner side of the chamber when viewed from above.

### Supplementary Note 12

In the substrate processing apparatus of any one of Supplementary Notes 8 to 11, an exhaust pipe configured to exhaust the another enclosure is connected to the another enclosure.

### Supplementary Note 13

According to another aspect of the present disclosure, there is provided a method of suppressing oxygen incorporation into a process gas supplied to a chamber of a substrate processing apparatus, the method comprising:
enclosing a supply source of the process gas and a connection pipe connecting the supply source and the chamber by an enclosure,
wherein the chamber is configured to be capable of being depressurized and accommodate a substrate.

According to the present disclosure in some embodiments, it is possible to suppress oxygen incorporation into a process gas supplied into a chamber of a substrate processing apparatus.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus, comprising:
a chamber configured to be capable of being depressurized and accommodate a substrate; and
an enclosure configured to enclose a supply source of a process gas supplied to the chamber and a connection pipe connecting the supply source and the chamber.

2. The substrate processing apparatus of claim 1, wherein a supply pipe configured to supply an inert gas into the enclosure and an exhaust pipe configured to exhaust the enclosure are each connected to the enclosure.

3. The substrate processing apparatus of claim 2, wherein the supply source is a vaporizer configured to store a raw material of the process gas and internally vaporize the raw material.

4. The substrate processing apparatus of claim 3, wherein the raw material is solid or liquid at room temperature and pressure.

5. The substrate processing apparatus of claim 4, wherein the raw material is a raw material gas which forms a ruthenium film through vaporization.

6. The substrate processing apparatus of claim 2, wherein the supply source is disposed to overlap the chamber when viewed from above.

7. The substrate processing apparatus of claim 6, wherein the enclosure is configured by:
a ceiling wall of the chamber; and
a cover configured to form an accommodation space, which accommodates the supply source and the connection pipe, between the cover and the ceiling wall,
wherein the cover is formed to fit into an inner side of the chamber when viewed from above.

8. The substrate processing apparatus of claim 7, further comprising another enclosure configured to enclose the enclosure.

9. The substrate processing apparatus of claim 8, wherein the another enclosure is configured by:
the ceiling wall of the chamber; and
another cover configured to form another accommodation space, which accommodates the supply source and the connection pipe together with the cover, between the another cover and the ceiling wall,
wherein the another cover is formed to fit into the inner side of the chamber when viewed from above.

10. The substrate processing apparatus of claim 6, further comprising another enclosure configured to enclose the enclosure.

11. The substrate processing apparatus of claim 2, further comprising another enclosure configured to enclose the enclosure.

12. The substrate processing apparatus of claim 11, wherein an exhaust pipe configured to exhaust the another enclosure is connected to the another enclosure.

13. The substrate processing apparatus of claim 1, wherein the supply source is a vaporizer configured to store a raw material of the process gas and internally vaporize the raw material.

14. The substrate processing apparatus of claim 1, wherein the supply source is disposed to overlap the chamber when viewed from above.

15. The substrate processing apparatus of claim 1, further comprising another enclosure configured to enclose the enclosure.

16. A method of suppressing oxygen incorporation into a process gas supplied to a chamber of a substrate processing apparatus, the method comprising:
enclosing a supply source of the process gas and a connection pipe connecting the supply source and the chamber by an enclosure,
wherein the chamber is configured to be capable of being depressurized and accommodate a substrate.
